(19) United States
(12) Patent Application Publication
(10) Pub. No.: US 2009/0072905 A1
(43) Pub. Date: Mar. 19, 2009

(54) VARIABLE GAIN AMPLIFIER HAVING WIDE GAIN VARIATION AND WIDE BANDWIDTH

(75) Inventors: Hoang Duong Quoc, Daejeon (KR); Eung Ju Kim, Suwon (KR); Sang Gug Lee, Daejeon (KR); Jeong Seon Lee, Daejeon (KR); Bong Rak Choi, Seoul (KR); Hong Bong Kim, Suwon (KR)

Correspondence Address: LOWE HAUPTMAN HAM & BERNER, LLP, 1700 DIAGONAL ROAD, SUITE 300, ALEXANDRIA, VA, 22314, US

(73) Assignee: Samsung Electro-Mechanics Co., Ltd., Suwon (KR)

(21) Appl. No.: 12/210,670

(22) Filed: Sep. 15, 2008

(30) Foreign Application Priority Data
Sep. 18, 2007 (KR) 10-2007-0094746

(51) Int. Cl. H03F 3/45

(52) U.S. Cl. 330/254

(57) ABSTRACT

There is provided a variable gain amplifier that is implemented with a CMOS device and has wide band variation and wide bandwidth by a predetermined exponential function. A variable gain amplifier having wide gain variation and wide bandwidth according to an aspect of the invention may include: a differential amplification section differentially amplifying an input signal according to a gain adjustment signal; and a gain adjustment section supplying the gain adjustment signal on the basis of an approximated exponential function determined according to a predetermined bias current, and adjusting a gain of the differential amplification section.

### CROSS-REFERENCE TO RELATED APPLICATIONS

This application claims the priority of Korean Patent Application No. 2007-0094746 filed on Sep. 18, 2007, in the Korean Intellectual Property Office, the disclosure of which is incorporated herein by reference.

### BACKGROUND OF THE INVENTION

1. Field of the Invention

The present invention relates to variable gain amplifiers, and more particularly, to a variable gain amplifier that is implemented with one CMOS device and has wide gain variation and wide bandwidth by a predetermined exponential function.

2. Description of the Related Art

In general, variable gain amplifiers (VGAs) are used to provide variable gain to various kinds of electronic apparatuses, such as disk drives, hearing aids, medical instruments, and communications apparatuses. Here, since the amplitude of signals used in the electronic apparatuses may vary over a wide range, gain variation needs to be as wide as possible. For example, code division multiple access (CDMA) communication systems require a gain variation of approximately 80 dB. That is, a region in which linear gain is obtained needs to be large on a dB scale.

An amplifier with linear variable gain on the dB scale can easily be obtained by using a bipolar transistor that provides the exponential I-V relationship. However, a CMOS transistor has nearly-linear I-V characteristics or exponential I-V characteristics that conform to the square-law in saturation-mode. Therefore, it is difficult to implement a CMOS variable gain amplifier with variable gain that is linear on the dB scale. Therefore, the CMOS variable gain amplifier is realized so that the gain thereof is based on an approximated exponential equation.

Examples of the approximated exponential equation, as known in the art, include Equation 1 and Equation 2 as follows. Equation 1 is a Taylor approximation function that is an approximated Taylor series expansion. Equation 2 is a pseudo-exponential function. Equation 1 and Equation 2 are given as follows:

$$\begin{matrix}{e}^{x} = 1 + \frac{x}{1 !} + \frac{{x}^{2}}{2 !} & Equation 1 \\ {e}^{x} = \frac{1 + x / 2}{1 - x / 2} & Equation 2\end{matrix}$$

FIG. 1 is a view illustrating curves on a dB scale by Equation 1 and Equation 2. Referring to FIG. 1, Equation 1 and Equation 2 are shown to have dB-linear variations of 12 dB and 15 dB with a linearity error of less than ±0.5 dB (error with respect to an ideal exponential function, indicated by dotted line), respectively. That is, Equation 1 offers a dB-linear range of approximately 12 dB, and Equation 2 offers a dB-linear range of approximately 15 dB. That is, variable gain amplifiers with gains by Equation 1 and Equation 2 can only vary in gain in the ranges of 12 dB and 15 dB, respectively.

FIG. 2 is an exemplary view illustrating an example of a variable gain amplifier that adopts Equation 2 according to the related art. As shown in FIG. 2, according to the related art, a variable gain amplifier includes a differential amplifier 21 having two MOS transistors M21 and M22, and diode-connected loads 22 connected to output terminals of the differential amplifier 21. According to the related art, the differential gain of the variable gain amplifier, shown in FIG. 2, is equal to g_{m-M21,M22}×Rout. Here, g_{m-M21,M22}×Rout is the transconductance of the diode-connected loads M23 and 24, and Rout is an output impedance. Since the output of the variable gain amplifier according to the related art is diode-connected loads, Rout is proportional to 1/g_{m-M23,M24}. Since the transconductance is a function of the bias current, the gain variation can be obtained by controlling the bias currents of an input pair M21 and M22 and the loads M23 and M24. According to the related art, the gain of the variable gain amplifier, shown in FIG. 2, can be obtained by the following equation:

$${A}_{v} = \frac{{g}_{m - M 21 , 22}}{{g}_{m - M 23 , 24}} = {[ \frac{{( W / L )}_{M 21 , 22}}{{( W / L )}_{M 23 , 24}} ( \frac{1 + x}{1 - x} ) ]}^{1 / 2} . \qquad Equation 3$$

Equation 3 is similar to the pseudo-exponential Equation as described in Equation 2. That is, the variable gain amplifier according to the related art, shown in FIG. 2, is designed on the basis of Equation 2. As a result, the variable gain amplifier can only offer a range of 15 dB with the linearity error of less than ±0.5 dB.

In order to widen the range of gain variation of the variable gain amplifier according to the related art, a variable gain amplifier has been generally implemented in multiple stages. As a result, the multi-stage variable gain amplifier consumes more power and requires a larger chip area, causing low noise characteristics and low linearity. In particular, an increase in the number of gain stages used causes reductions in the noise characteristics and the linearity.

In consideration of frequency response of the circuit, shown in FIG. 2, the bandwidth of the variable gain amplifier is determined by input and output poles. Since the output loads are diode-connected transistors, the output pole is mainly dependent on the bias current of the transistors M23 and M24. At a lower gain setting, I₀ (1−x) and the bandwidth are extended. However, at a higher gain setting, I₀ (1−x) is reduced, and the bandwidth is reduced. The input pole is a function of input capacitance. In FIG. 2, the total capacitance at the input node of the MOS transistor M21 is equal to the sum of a capacitance C_{GS} between a gate and a source and the Miller multiplication of a capacitance C_{GD} between the gate and a drain, that is, C_{GS}+(1+|Aᵥ|)C_{GD}. As a result, the input pole is proportional to the gain, such that the bandwidth is significantly reduced at the higher gain setting.

Therefore, there has been required a variable gain amplifier that can reduce the number of stages providing gains to consume a small amount of bias current and use a small chip area, have wide gain variation, and provide wide bandwidth even at high gains.

### SUMMARY OF THE INVENTION

An aspect of the present invention provides a variable gain amplifier that is implemented with a CMOS device and has wide gain variation and wide bandwidth by a predetermined exponential function.

According to an aspect of the present invention, there is provided a variable gain amplifier having wide gain variation and wide bandwidth, the variable gain amplifier including: a differential amplification section differentially amplifying an input signal according to a gain adjustment signal; and a gain adjustment section supplying the gain adjustment signal on the basis of an approximated exponential function determined according to a predetermined bias current, and adjusting a gain of the differential amplification section.

The approximated exponential function may satisfy the following equation:

$$f ( x ) = \frac{[ 1 + ax + {k ( ax )}^{2} / 2 ]}{[ 1 - ax + {k ( ax )}^{2} / 2 ]} , \qquad Equation$$

where k and a are constants determined by the bias current, and x is an independent variable.

The gain adjustment section may include a current converter converting a current level of a predetermined adjustment signal into a current level of the gain adjustment signal having a different current level from that of the adjustment signal.

The gain adjustment section may further include: a voltage-to-current converter converting a voltage level of a control signal from the outside into the current level of the adjustment signal; and a bias circuit supplying the bias current to the voltage-to-current converter.

The current converter may include: a plurality of amplification units connected in parallel with each other and each having at least two amplifier devices connected in series to each other between a driving power supply terminal supplying predetermined driving power and a ground terminal; and a current squaring unit connected in parallel with the amplification units between the driving power supply terminal and the ground terminal, and having a plurality of amplifier devices mirroring a current from the amplification units.

The voltage-to-current converter may include: a level converting circuit having a plurality of amplifier devices connected in parallel with each other between a driving power supply terminal supplying predetermined driving power and a ground terminal, and converting a voltage level of the adjustment signal into a current level; and a current mirror circuit having a plurality of amplifier devices connected in parallel with each other between the level converting circuit and the ground terminal, and mirroring a current from the level converting circuit.

The bias circuit may include: a bias unit mirroring a current from the predetermined driving power and supplying the bias current; and a cascode amplification unit amplifying the bias current.

The differential amplification section may further include: a cascode input terminal increasing an operating frequency bandwidth by adjusting the capacitance of an input terminal of the input signal; and an inductive active load connected to an output terminal of the differential amplification section, adjusting the capacitance of the output terminal, and increasing an operating frequency bandwidth.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a graph illustrating an approximated exponential function that is applied to gain variation of a variable gain amplifier according to the related art;

FIG. 2 is circuit diagram illustrating one example of the variable gain amplifier according to the related art;

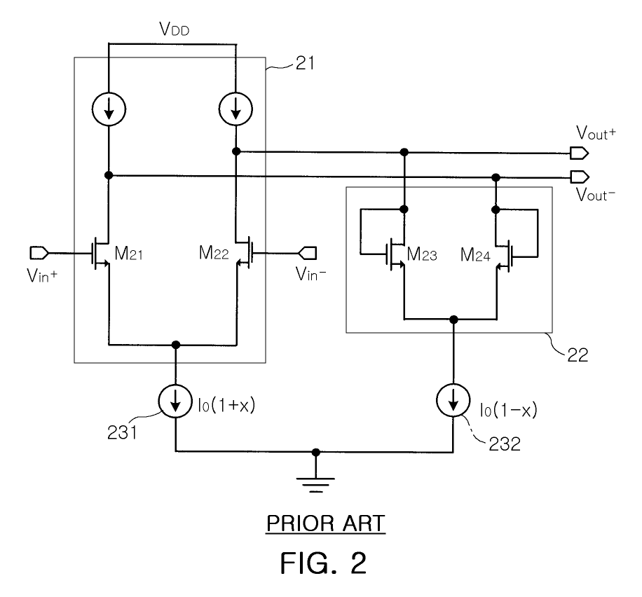

FIG. 3 is a configuration view illustrating a variable gain amplifier according to an exemplary embodiment of the invention;

FIG. 4 is a graph of an approximated exponential function that is applied to gain variation of the variable gain amplifier according to the embodiment of the invention;

FIG. 5 is a circuit diagram illustrating a voltage-to-current converter that is used in the variable gain amplifier according to the embodiment of the invention;

FIG. 6 is a circuit diagram illustrating one example of a differential amplification section that is used in the variable gain amplifier according to the embodiment of the invention;

FIG. 7 is a circuit diagram illustrating another example of a differential amplification section that is used in the variable gain amplifier according to the embodiment of the invention;

FIG. 8 is a circuit diagram illustrating a voltage-to-current converter that is used in the variable gain amplifier according to the embodiment of the invention; and

FIG. 9 is a circuit diagram illustrating a bias circuit that is used in the variable gain amplifier according to the embodiment of the invention.

### DETAILED DESCRIPTION OF THE PREFERRED EMBODIMENT

Exemplary embodiments of the present invention will now be described in detail with reference to the accompanying drawings.

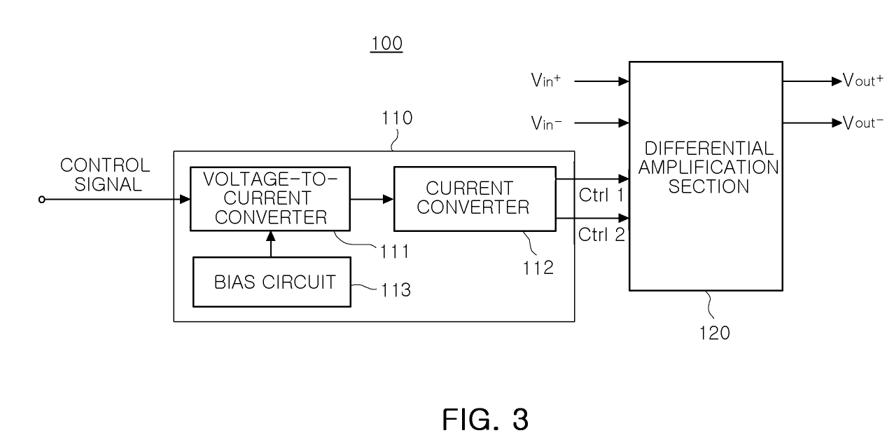

FIG. 3 is a configuration view illustrating a variable gain amplifier according to an exemplary embodiment of the invention.

Referring to FIG. 3, a variable gain amplifier 100 according to an exemplary embodiment of the invention may include a gain adjustment section 110 and a differential amplification section 120.

The gain adjustment section 110 adjusts a gain of the differential amplification section 120 by a predetermined approximated exponential function.

The gain adjustment section 110 includes a current converter 112. When a control signal supplied from the outside is a current signal, the current converter 112 converts a voltage level of the current signal into a predetermined current level. The gain adjustment section 110 further includes a voltage-to-current converter 111 and a bias circuit 113. When the control signal is a voltage signal, the voltage-to-current converter 111 converts a voltage level of the voltage signal into a current level. The bias circuit 113 supplies a predetermined bias current to the voltage-to-current converter 111.

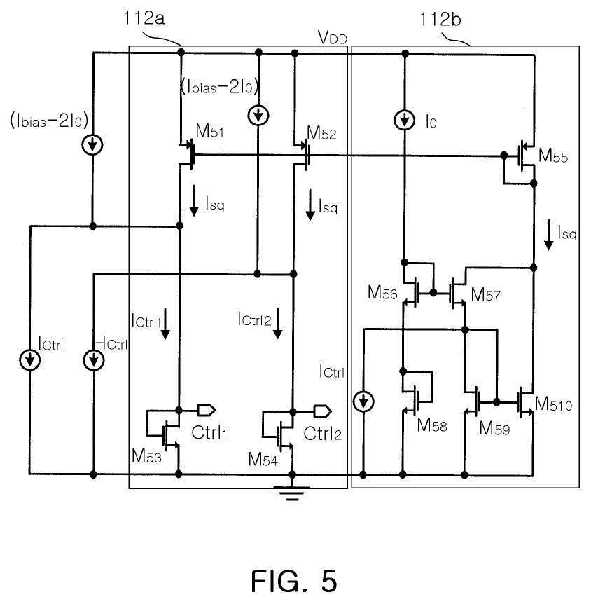

FIG. 5 is a circuit diagram illustrating a current converter that is used in the variable gain amplifier according to the exemplary embodiment of the invention.

Referring to FIG. 5, the current converter 112 used in the variable gain amplifier 100 according to the embodiment includes a plurality of amplification units 112a and a current squaring unit 112b.

The amplification units 112a and the current squaring unit 112b are connected in parallel with each other between a ground terminal and a driving power supply terminal that supplies a predetermined driving current VDD.

Each of the amplification units 112a includes a plurality of amplifier devices M51, M52, M53, and M54. The amplifier device M51 and the amplifier device M53 are connected in series with each other. The amplifier device M52 and the amplifier device M54 are connected in series with each other. The amplifier devices M51 and M53 are in parallel with the amplifier devices M52 and M54, respectively.

The current squaring unit 112b includes a plurality of amplifier devices M55, M56, M57, M58, M59, and M510. A gate of the amplifier device M55 is connected to gates of the amplifier devices M51 and M52 of the amplification unit 112a. A gate of the amplifier device M56 is connected to a gate of the amplifier device M57. Further, the amplifier device M58 is cascade-connected to the amplifier device M56. A gate of the amplifier device M59 is connected to a gate of the amplifier device M510.

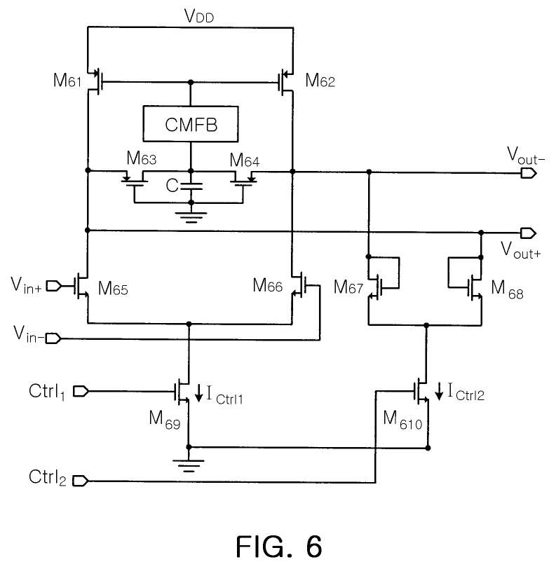

FIG. 6 is a circuit diagram illustrating an example of a differential amplification section that is used in the variable gain amplifier according to the embodiment of the invention.

Referring to FIG. 6, the differential amplification section 120 used in the variable gain amplifier 100 includes a plurality of amplifier devices M61, M62, M63, M64, M65, M66, M67, M68, M69, and M610, and a common mode feedback block CMFB. Input signals Vin+ and Vin− are input to gates of the amplifier devices M65 and M66, respectively.

The amplifier devices M61 and M62 are located between the driving power supply terminal and the ground terminal, and are connected in series with the amplifier devices M65 and M66, respectively. The common mode feedback block CMFB and the amplifier devices M63 and M64 are connected between the amplifier devices M61 and M62, and the amplifier devices M65 and M66. Amplified output signals Vout+ and Vout are output from source terminals of the amplifier devices M63 and M64, respectively.

The amplifier devices M67 and M68 are connected to output terminals of the output signals Vout+ and Vout, respectively. A control signal Ctrl1 is input through a gate terminal of the amplifier device M69. The amplifier devices M610 has a drain terminal that is connected to source terminals of the amplifier devices M67 and M68, and a gate terminal through which a control signal Ctrl2 is input.

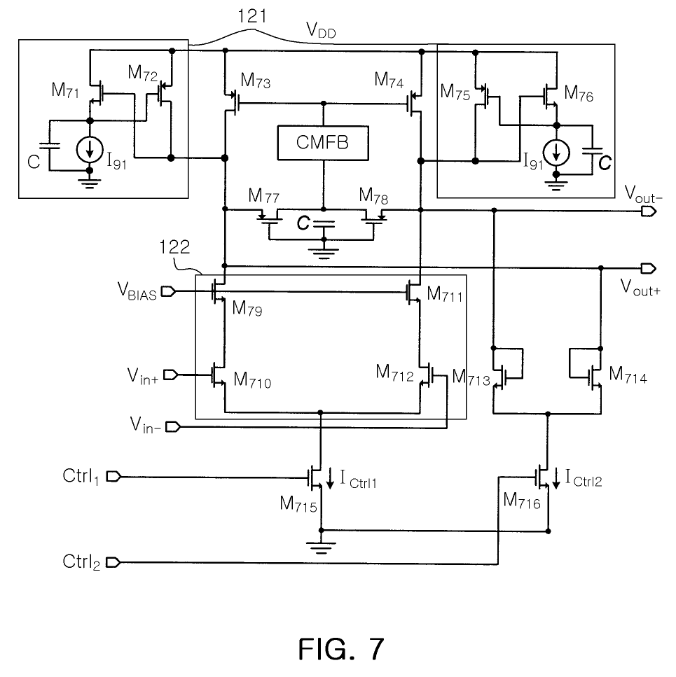

FIG. 7 is a circuit diagram illustrating another example of a differential amplification section that is used in the variable gain amplifier according to the embodiment of the invention.

Referring to FIG. 7, another example of the differential amplification section 120 of the variable gain amplifier according to the embodiment of the invention may further include an active inductive load 121 and a cascode input terminal 122.

The active inductive load 121 may include a capacitor C, a current source 191, and amplifier devices M71, M72, M75, and M76 that are connected in parallel with each other. An active inductive load 121 may be connected to output terminals of output signals Vout+ and Vout−.

The cascode input terminal 122 may have input terminals of input signals Vin+ and Vin− that are connected in cascode. Bias power V_{BIAS} may be supplied to gates of amplifier devices M79 and M711. The input signals Vin+ and Vin− may be input to gate terminals of amplifier devices M710 and M712 that are cascode-connected to the amplifier devices M79 and M711, respectively.

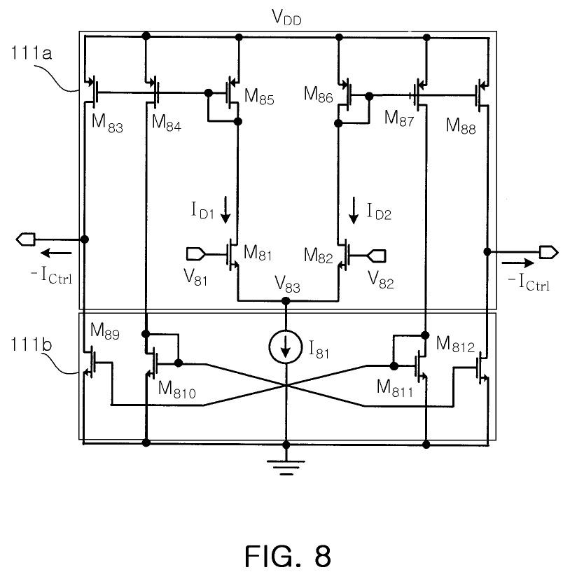

FIG. 8 is a circuit diagram illustrating a voltage-to-current converter that is used in the variable gain amplifier according to the embodiment of the invention.

Referring to FIG. 8, when a control signal that is transmitted to the variable gain amplifier according to the embodiment of the invention is a voltage signal, the voltage-to-current converter 111 may be used. The voltage-to-current converter 111 may include a current conversion circuit 111a and a current mirror circuit 111b.

The current conversion circuit 111a includes a plurality of amplifier devices M81 to M88. The current mirror circuit 111b includes a plurality of amplifier devices M89, M810, M811, and M812 whose gates are connected to each other to mirror a current.

The plurality of amplifier devices M83, M84, M85, M86, M87, M88 of the current conversion circuit 111a are connected in parallel with each other between the driving power supply terminal and the ground terminal. The amplifier devices M81 and M82 are connected in series to the amplifier devices M85 and M86, respectively. Voltages V81 and V82 of control signals from the outside are applied to gates of the amplifier devices M81 and M82, respectively. Signals +Ictrl and −Ictrl having a predetermined voltage level are output from drain terminals of the amplifier devices M83 and M88, respectively.

The current mirror circuit 111b is connected in series between the current conversion circuit 111a and the ground terminal. A gate of the amplifier device M89 is connected to a gate of the amplifier device M811. A gate of the amplifier device M810 is connected to a gate of the amplifier device M812.

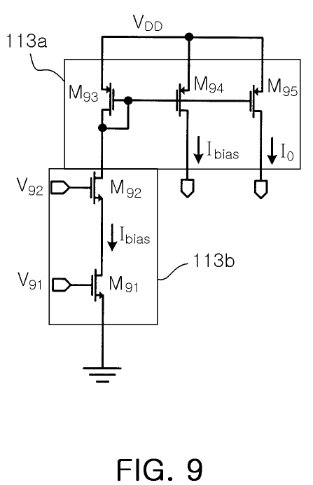

FIG. 9 is a circuit diagram illustrating a bias circuit that is used in the variable gain amplifier according to the embodiment of the invention.

Referring to FIG. 9, the bias circuit 113 that is used in the variable gain amplifier according to the embodiment of the invention includes a bias unit 113a and a cascode amplification unit 113b.

The bias unit 113a includes a plurality of amplifier device M93, M94, and M95 that are connected in parallel with each other between the driving power supply terminal and the ground terminal. The amplifier device M93, M94, and M95 have gates connected in common with each other to mirror a current and supply predetermined bias currents Ibias and Io.

The cascode amplification unit 113b is connected in series between the bias unit 113a and the ground terminal, and includes amplifier device M91 and M92 that are connected in cascode to amplify the bias current Ibias.

Hereinafter, the operation and effect of the invention will be described in detail.

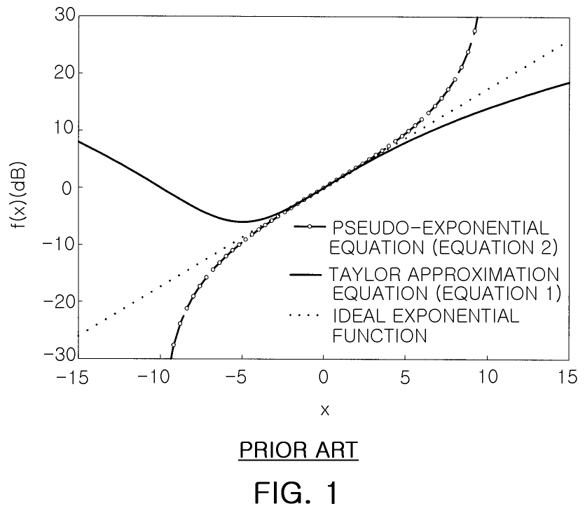

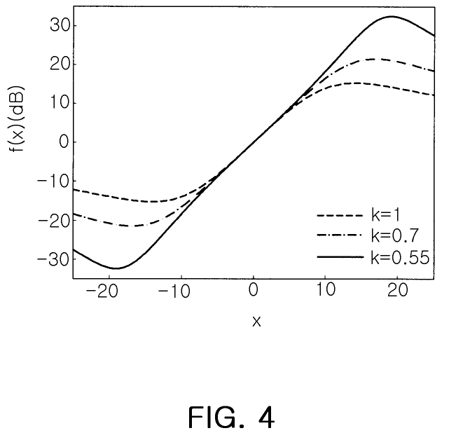

In order to solve the problem in the variable gain amplifier that is implemented on the basis of the above-described function in the related art with reference to FIG. 1, the invention proposes a new approximated exponential equation. An approximated exponential equation that is proposed in this invention satisfies the following equation:

$$f ( x ) = \frac{[ 1 + ax + {k ( ax )}^{2} / 2 ]}{[ 1 - ax + {k ( ax )}^{2} / 2 ]} , \qquad Equation 4$$

where k and a are constants, and x is an independent variable. FIG. 4 is a graph with a dB scale of Equation 4 according to a change in value k. As shown in FIG. 4, when k=1 is satisfied, a linear range of approximately 20 dB with a linearity error of ±0.5 dB or less is provided by Equation 4. When the value k is less than 1, the dB-linear range based on Equation 4 increases sharply. When k=0.55 is satisfied, a dB-linear range of 65 dB or more can be provided. When compared with the linear ranges based on Equation 1 and Equation 2, a dB-linear range of the gain variation of the variable gain amplifier can be increased by 50 to 55 dB by using Equation 4 that is used in this embodiment of the invention. Therefore, in a case of the variable gain amplifier to which Equation 4 is applied, a one-stage variable gain amplifier can provide a dB-linear gain of approximately 65 dB or more. When compared with a one-stage variable gain amplifier that adopts Equation 1 and Equation 2 according to the related art, the dB linear gain variation can be significantly improved.

FIG. 5 is a circuit diagram illustrating a current converter 112 that is used in the variable gain amplifier 100 according to the embodiment of the invention.

Referring to FIG. 5, the amplifier devices M51 to M59 and M510 of the current converter 112 is biased in saturation region. The control signals Ctrl1 and Ctrl2 are transmitted to the differential amplification section 120. A current Ictrl will be described in more detail below. A drain current Isq of the amplifier device M55 and the input current Ictrl satisfy the following equation:

I_{sq}=2I₀+I_{Ctrl}²/8I₀ Equation 5,

where Io is a bias current. The drain current Isq can be expressed by the sum of the current mirrored by the amplifier device M51 and the amplifier device M52 and a bias current Ibias-2Io. Therefore, currents Ictrl1 and the Ictrl2 satisfy the following equation:

$$\begin{matrix}{I}_{Ctrl 1} = {I}_{sq} + ( {I}_{bias} - 2 {I}_{0} ) - {I}_{Ctrl} \\ = {I}_{bias} - {I}_{Ctrl} + \frac{{I}_{Ctrl}^{2}}{8 {I}_{0}} \\ = {I}_{bias} ( 1 - \frac{{I}_{Ctrl}}{{I}_{bias}} + \frac{{I}_{Ctrl}^{2}}{8 {I}_{0} {I}_{bias}} )\end{matrix} \\ \begin{matrix}{I}_{Ctrl 2} = {I}_{sq} + ( {I}_{bias} - 2 {I}_{0} ) - {I}_{Ctrl} \\ = {I}_{bias} + {I}_{Ctrl} + \frac{{I}_{Ctrl}^{2}}{8 {I}_{0}} \\ = {I}_{bias} ( 1 + \frac{{I}_{Ctrl}}{{I}_{bias}} + \frac{{I}_{Ctrl}^{2}}{8 {I}_{0} {I}_{bias}} ) ,\end{matrix} \qquad Equation 6$$

where the currents Ictrl1 and Ictrl2 are the current Ictrl of an adjustment signal. The currents Ictrl1 and Ictrl2 are used to adjust the gain of the differential amplification section 120.

The differential amplification section 120, shown in FIG. 6, includes the common-source connected amplifier devices M65 and M66, and amplifier devices M67 and M68 that are diode-connected loads. The common mode feedback block CMFB maintains voltage levels of the output DC voltages Vout+ and Vout− at predetermined voltages levels.

Like Equation 3, the gain of the variable gain amplifier according to the embodiment of the invention can be determined by the following equation:

$${A}_{v} = \frac{{G}_{m , {M}_{65 , 66}}}{{g}_{m , {M}_{67 , 68}}} = \sqrt{\frac{{μ}_{n} {{C}_{ox} ( W / L )}_{{M}_{65 , 66}} {I}_{Ctrl 1}}{{μ}_{n} {{C}_{ox} ( W / L )}_{{M}_{67 , 68}} {I}_{Ctrl 2}}} , \qquad Equation 7$$

where g_{m-M65,M66} is transconductance of the amplifier devices M65 and M66 connected to each other at a common source terminal, g_{m-M67,68} is transconductance of the amplifier devices M67 and M68 of the diode-connected loads. Further, (W/L)_{M65,66} is a ratio between an area and a width of the amplifier devices M65 and M66, and (W/L)_{M67,68} is a ratio between an area and a width of the amplifier devices M67 and M68 of the diode-connected loads.

If (W/L)_{M65,66}=(W/L)_{M67,68} is satisfied in Equation 7, and Equation 5 and Equation 6 are substituted into Equation 7, the gain of the variable gain amplifier according to the embodiment of the invention can be expressed by the following equation:

$$\begin{matrix}{A}_{v} = M \frac{{( 1 + \frac{{I}_{Ctrl}}{{I}_{bias}} + \frac{{I}_{Ctrl}^{2}}{8 {I}_{0} {I}_{bias}} )}^{1 / 2}}{{( 1 - \frac{{I}_{Ctrl}}{{I}_{bias}} + \frac{{I}_{Ctrl}^{2}}{8 {I}_{0} {I}_{bias}} )}^{1 / 2}} \\ = M {( \frac{1 + ax + {k ( ax )}^{2} / 2}{1 - ax + {k ( ax )}^{2} / 2} )}^{1 / 2} ,\end{matrix} \qquad Equation 8$$

where M=(W/L)_{M65,66}/(W/L)_{M67,68}, and a=1/I_{BIAS}, k=I_{BIAS}/4Io are satisfied. The variable gain amplifier according to the embodiment of the invention can provide dB-linear gain by Equation 4 that is the approximated exponential equation proposed in the embodiment of the invention. In Equation 8, k, I_{BIAS}, and Io are fixed values that are determined by physical characteristics of the amplifier devices M65, M66, M67, and M68. Therefore, when the current from the gain adjustment section 110 of the variable gain amplifier is adjusted to satisfy k=0.55, that is, when the current Ictrl of the adjustment signal is adjusted so that the current I_{BIAS} is equal to 2.2Io, the gain of the variable gain amplifier can provide the linear variation range of approximately 65 dB or more, as shown in FIG. 4, despite one amplification stage.

Referring to FIG. 7, the active inductive load 121 and the cascode input terminal 122 are provided in the differential amplification unit 120 that is included in the variable gain amplifier.

The active inductive load 121 is connected to the first output voltage source Vout+ terminal and the second output voltage source Vout− terminal.

The operation of the active inductive load 121 will now be described. The amplifier devices M72 operates as a load. The amplifier devices M71 and the amplifier devices M72 operating as the load are connected to form negative feedback. Further, the capacitor C improves frequency characteristics by allowing the first output DC voltage Vout+ terminal to have zero, that is, the bandwidth of the variable gain amplifier is extended. Therefore, by controlling the capacitance of the capacitor C, a desired gain can be obtained at desired operating frequency. The operation is equally performed by the amplifier devices M75 and M76, the current source 191 and the capacitor C so as to cause the second output Dc voltage Vout-terminal to have “zero”, such that frequency characteristics are improved.

At the cascode input terminal 122, when each of the amplifier devices M79, M710, M711, M712 has the same ratio between a width W and a length L (that is, (W/L)_{M79}=(W/L)_{M710}=(W/L)_{M711}=(W/L) M₇₁₂ is satisfied), a differential gain g_{m-M711}/g_{m-M79} between the input terminals of the input signals Vin+ and Vin− and the drain terminals of the amplifier devices M711 and M712 becomes 1. Therefore, the Miller multiplication reaches the minimum value, and thus the input capacitance reaches the minimum value. As a result, the input pole is moved toward a higher frequency, and the bandwidth at which the variable gain amplifier operates is further increased.

As such, in the embodiment of the invention, a wide linear gain variation range of 65 dB or more can be ensured by one wide stage, and the narrowing of frequency bandwidth can be prevented despite an increase in gain.

The gain adjustment section 110 of the variable gain amplifier 100 according to the embodiment of the invention may further include the voltage-to-current converter 111 and the bias circuit 113.

Referring to FIG. 8, the amplifier devices M81 to M89 and M810 to M812 of the voltage-to-current converter 111 are biased in saturation region. Here, the input voltages V81 and V82 are V_{BIAS}±V_{CTRL}/2, V_{BIAS} is a predetermined DC bias voltage, and V_{CTRL} is a voltage level of the adjustment signal. The current level Ictrl of the adjustment signal converted by the voltage-to-current converter 111 can be expressed by the following equation:

$$\begin{matrix}{I}_{Ctrl} = - {I}_{Ctrl} \\ = ( {I}_{D 1} - {I}_{D 2} ) \\ = ( {μ}_{n} {C}_{ox} \frac{W}{L} ) ( {V}_{BIAS} - {V}_{83} - {V}_{TH} ) {V}_{CTRL} ,\end{matrix} \qquad Equation 9$$

where I_{D1}, I_{D2}, V83, and Vₜₕ are the drain currents, the source and threshold voltages of the amplifier devices M81 and M82.

Referring to FIG. 9, the amplifier devices M93 of the bias circuit 113 that is used in the gain adjustment section 110 according to this embodiment of the invention operates in the triode region (V_{DS}<<2(V_{GS}−V_{TH}). The currents Io and I_{BIAS} are supplied from the current converter 112 of FIG. 5. Here, when k=0.55 is satisfied, the gain of the variable gain amplifier 100 has a wide range. The current I_{BIAS} can be expressed by the following equation:

$${I}_{bias} = {μ}_{n} {C}_{ox} \frac{W}{L} ( {V}_{91} - {V}_{TH} ) {V}_{DS} \qquad Equation 10$$

If k=I_{BIAS}/4Io is applied to Equation 8, Equation 9, and Equation 10, the gain of the variable gain amplifier 100 can be expressed by the following equation:

$$\begin{matrix}{A}_{v} = M \frac{{( 1 + \frac{{I}_{Ctrl}}{{I}_{bias}} + \frac{{I}_{Ctrl}^{2}}{8 {I}_{0} {I}_{bias}} )}^{1 / 2}}{{( 1 - \frac{{I}_{Ctrl}}{{I}_{bias}} + \frac{{I}_{Ctrl}^{2}}{8 {I}_{0} {I}_{bias}} )}^{1 / 2}} \\ = M \frac{{( 1 + \frac{{I}_{Ctrl}}{{I}_{bias}} + \frac{{kI}_{Ctrl}^{2}}{2 {I}_{bias}} )}^{1 / 2}}{{( 1 - \frac{{I}_{Ctrl}}{{I}_{bias}} + \frac{{kI}_{Ctrl}^{2}}{2 {I}_{bias}} )}^{1 / 2}} \\ = {M ( \frac{\begin{matrix}1 + \frac{( {V}_{BIAS} - {V}_{83} - {V}_{TH} )}{( {V}_{91} - {V}_{TH} )} \times {V}_{CTRL} + \\ k [ \frac{( {V}_{BIAS} - {V}_{83} - {V}_{TH} )}{( {V}_{91} - {V}_{TH} )} ] \times \frac{{V}_{CTRL}^{2}}{2}\end{matrix}}{\begin{matrix}1 + \frac{( {V}_{BIAS} - {V}_{83} - {V}_{TH} )}{( {V}_{91} - {V}_{TH} )} \times {V}_{CTRL} + \\ k [ \frac{( {V}_{BIAS} - {V}_{83} - {V}_{TH} )}{( {V}_{91} - {V}_{TH} )} ] \times \frac{{V}_{CTRL}^{2}}{2}\end{matrix}} )}^{1 / 2} \\ = {M ( \frac{1 + ax + {k ( ax )}^{2} / 2}{1 - ax + {k ( ax )}^{2} / 2} )}^{1 / 2} ,\end{matrix} \qquad Equation 11$$

where a=(V_{BIAS}−V83−V_{TH})/(V91−V_{TH})V_{DS} is satisfied, and x=Vctrl is satisfied. Here, if V_{BIAS}−V83=V91 is satisfied, the gain of the variable gain amplifier 100 can be calculated by the following equation:

$$\begin{matrix}{A}_{v} = {M ( \frac{1 + \frac{{V}_{CTRL}}{{V}_{DS}} + \frac{k}{{V}_{DS}^{2}} \times \frac{{V}_{CTRL}^{2}}{2}}{1 - \frac{{V}_{CTRL}}{{V}_{DS}} + \frac{k}{{V}_{DS}^{2}} \times \frac{{V}_{CTRL}^{2}}{2}} )}^{1 / 2} \\ = M {( \frac{1 + ax + {k ( ax )}^{2} / 2}{1 - ax + {k ( ax )}^{2} / 2} )}^{1 / 2} ,\end{matrix} \qquad Equation 12$$

where a=1/V_{DS} is satisfied, and the x=Vctrl is satisfied.

As described above, the variable gain amplifier 100 according to the embodiment of the invention can have wide gain variation and wide bandwidth by adjusting the gain on the basis of the proposed approximated exponential equation.

As set forth above, according to the exemplary embodiments of the invention, the variable gain amplifier is implemented by using the approximated exponential equation, as shown in FIG. 4, such that a wide dB-linear range of approximately 65 dB or more can be ensured at one single stage.

Further, according to the embodiment of the invention, even when the variable gain amplifier is determined to have a high gain, the narrowing of the bandwidth can be prevented.

While the present invention has been shown and described in connection with the exemplary embodiments, it will be apparent to those skilled in the art that modifications and variations can be made without departing from the spirit and scope of the invention as defined by the appended claims.

What is claimed is:

1. A variable gain amplifier having wide gain variation and wide bandwidth, the variable gain amplifier comprising:
a differential amplification section differentially amplifying an input signal according to a gain adjustment signal; and
a gain adjustment section supplying the gain adjustment signal on the basis of an approximated exponential function determined according to a predetermined bias current, and adjusting a gain of the differential amplification section.

2. The variable gain amplifier of claim 1, wherein the approximated exponential function satisfies the following equation:
$$f ( x ) = \frac{[ 1 + ax + {k ( ax )}^{2} / 2 ]}{[ 1 - ax + {k ( ax )}^{2} / 2 ]} , \qquad Equation$$
where k and a are constants determined by the bias current, and x is an independent variable.

3. The variable gain amplifier of claim 1, wherein the gain adjustment section comprises a current converter converting a current level of a predetermined adjustment signal into a current level of the gain adjustment signal having a different current level from that of the adjustment signal.

4. The variable gain amplifier of claim 3, wherein the gain adjustment section further comprises:
a voltage-to-current converter converting a voltage level of a control signal from the outside into the current level of the adjustment signal; and
a bias circuit supplying the bias current to the voltage-to-current converter.

5. The variable gain amplifier of claim 3, wherein the current converter comprises:
a plurality of amplification units connected in parallel with each other and each having at least two amplifier devices connected in series to each other between a driving power supply terminal supplying predetermined driving power and a ground terminal; and
a current squaring unit connected in parallel with the amplification units between the driving power supply terminal and the ground terminal, and having a plurality of amplifier devices mirroring a current from the amplification units.

6. The variable gain amplifier of claim 4, wherein the voltage-to-current converter comprises:
a level converting circuit having a plurality of amplifier devices connected in parallel with each other between a driving power supply terminal supplying predetermined driving power and a ground terminal, and converting a voltage level of the adjustment signal into a current level; and
a current mirror circuit having a plurality of amplifier devices connected in parallel with each other between the level converting circuit and the ground terminal, and mirroring a current from the level converting circuit.

7. The variable gain amplifier of claim 4, wherein the bias circuit comprises:
a bias unit mirroring a current from the predetermined driving power and supplying the bias current; and
a cascode amplification unit amplifying the bias current.

8. The variable gain amplifier of claim 1, wherein the differential amplification section further includes:
a cascode input terminal increasing an operating frequency bandwidth by adjusting the capacitance of an input terminal of the input signal; and
an inductive active load connected to an output terminal of the differential amplification section, adjusting the capacitance of the output terminal, and increasing an operating frequency bandwidth.
